(19) United States
(12) Patent Application Publication
(10) Pub. No.: US 2023/0226643 A1
(43) Pub. Date: Jul. 20, 2023

(54) LASER ABLATION DEVICE AND DISPLAY DEVICE MANUFACTURING METHOD USING THE SAME

(71) Applicant: Samsung Display Co., Ltd., Yongin-si (KR)

(72) Inventors: JOONHYUNG KIM, Asan-si (KR); WOOHYUN KIM, Hwaseong-si (KR); DAEWOANG PARK, Cheonan-si (KR); SEUNGIL JANG, Cheonan-si (KR)

(21) Appl. No.: 17/970,390

(22) Filed: Oct. 20, 2022

(30) Foreign Application Priority Data
Jan. 20, 2022 (KR) 10-2022-0008784

(51) Int. Cl. B23K 26/36; B23K 26/06; B23K 26/073

(52) U.S. Cl. CPC B23K 26/36; B23K 26/0648; B23K 26/0736; B23K 26/0604; B23K 2101/36

(57) ABSTRACT

A laser ablation device includes: a laser irradiation part to emit a plurality of solid-state laser beams; an optical system to convert the plurality of solid-state laser beams into output light; and a stage to receive an irradiation target to be irradiated with the output light. A minor axis of the output light has a semi-super Gaussian profile of order 2 to order 2.4.

### CROSS-REFERENCE TO RELATED APPLICATIONS

This application claims priority to and the benefit of Korean Patent Application No. 10-2022-0008784, filed on Jan. 20, 2022, the entire content of which is incorporated by reference herein.

### BACKGROUND

### 1. Field

Aspects of embodiments of the present disclosure relate to a laser ablation device, and a display device manufacturing method using the same.

### 2. Description of the Related Art

A display device is formed via various processes. During the processes, a base substrate for processing may be provided to support or protect a display panel. Thereafter, the base substrate for processing may be removed from the display panel, and various optical members or a window may be coupled to the display panel.

The above information disclosed in this Background section is for enhancement of understanding of the background of the present disclosure, and therefore, it may contain information that does not constitute prior art.

### SUMMARY

One or more embodiments of the present disclosure are directed to a laser ablation device, which reduces or removes a display device defect.

One or more embodiments of the present disclosure are directed to a display device manufacturing method using a laser ablation device, which reduces or removes a display device defect.

According to one or more embodiments of the present disclosure, a laser ablation device includes: a laser irradiation part configured to emit a plurality of solid-state laser beams; an optical system configured to convert the plurality of solid-state laser beams into output light; and a stage configured to receive an irradiation target to be irradiated with the output light. A minor axis of the output light has a semi-super Gaussian profile of order 2 to order 2.4.

In an embodiment, an energy intensity per unit area of the output light delivered to the irradiation target may be about 130 mJ/cm² to about 200 mJ/cm².

In an embodiment, the optical system may include: a first molded lens configured to change initial shapes of the plurality of solid-state laser beams into first shapes; and a second molded lens configured to change the first shapes of the plurality of solid-state laser beams into second shapes different from the first shapes.

In an embodiment, the optical system may further include a shape rotation lens configured to rotate the second shapes of the plurality of solid-state laser beams passed through the second molded lens.

In an embodiment, the shape rotation lens may rotate, by about 90 degrees, the second shapes of the plurality of solid-state laser beams passed through the second molded lens.

In an embodiment, the optical system may further include a homogenizer configured to mix the plurality of solid-state laser beams passed through the shape rotation lens to output mixed light.

In an embodiment, the optical system may further include: a third molded lens configured to change a shape of the mixed light to a third shape; and a fourth molded lens configured to change the third shape of the mixed light passed through the third molded lens into a fourth shape different from the third shape.

In an embodiment, each of the first molded lens, the second molded lens, the third molded lens, and the fourth molded lens may be a cylindrical lens.

In an embodiment, a radius of curvature of the fourth molded lens may be about 5200 mm to about 7000 mm.

In an embodiment, each of the first shapes and the second shapes may be an ellipse.

In an embodiment, initial shapes of the plurality of solid-state laser beams may be circular, and a number of the plurality of solid-state laser beams may be at least 4.

In an embodiment, the laser ablation device may further include a lower optical system configured to combine the plurality of solid-state laser beams emitted by the laser irradiation part with one another, and provide the optical system with a plurality of solid-state laser beams having initial shapes and a number that is smaller than the number of the plurality of solid-state laser beams emitted by the laser irradiation part.

In an embodiment, irradiation regions of the output light emitted toward the irradiation target may overlap with each other by at least about 66.7%.

According to one or more embodiments of the present disclosure, a laser ablation device includes: a laser irradiation part configured to emit a plurality of solid-state laser beams; an optical system configured to convert the plurality of solid-state laser beams into output light; and a stage configured to receive an irradiation target to be irradiated with the output light. A minor axis of the output light has a semi-super Gaussian profile, and a width at about 90% of a maximum of the semi-super Gaussian profile is about 18 micrometers to about 40 micrometers.

In an embodiment, the semi-super Gaussian profile may be of order 2 to order 2.4.

According to one or more embodiments of the present disclosure, a display device manufacturing method includes: forming a display panel on a base substrate for processing; and emitting output light to separate the display panel from the base substrate for processing. The emitting of the output light includes: converting a plurality of solid-state laser beams into the output light, and emitting the output light in a direction from the base substrate for processing toward the display panel. A minor axis of the output light has a semi-super Gaussian profile of order 2 to order 2.4.

In an embodiment, the converting of the plurality of solid-state laser beams into the output light may include: changing shapes of the plurality of solid-state laser beams to first shapes; changing the first shapes of the plurality of solid-state laser beams into second shapes different from the first shapes; rotating the second shapes of the plurality of solid-state laser beams; and mixing the plurality of solid-state laser beams with one another to output mixed light.

In an embodiment, the converting of the plurality of solid-state laser beams into the output light may further include: changing a shape of the mixed light to a third shape; and changing the third shape into a fourth shape different from the third shape.

In an embodiment, the display panel may include a first area, and a second area adjacent to the first area, the second area having a lower transmittance than that of the first area.

In an embodiment, the display panel may have a transmittance of about 79% to about 86%.

### BRIEF DESCRIPTION OF THE DRAWINGS

The above and other aspects and features of the present disclosure will be more clearly understood from the following detailed description of the illustrative, non-limiting embodiments with reference to the accompanying drawings. In the drawings:

FIG. 1A is a perspective view of a display panel during a manufacturing process according to an embodiment of the present disclosure;

FIG. 1B is a cross-sectional view of the display panel according to an embodiment of the present disclosure;

FIG. 2 is a plan view of a display panel according to an embodiment of the present disclosure;

FIG. 3 is a view illustrating an operation of a laser ablation device according to an embodiment of the present disclosure;

FIG. 4 is a schematic view of a laser ablation device according to an embodiment of the present disclosure;

FIGS. 5A-5G are views illustrating a shape of a laser beam according to one or more embodiments of the present disclosure;

FIGS. 6A-6B are Gaussian graphs of a laser ablation device according to a comparative example;

FIG. 7 is a Gaussian graph of a laser ablation device according to an embodiment of the present disclosure;

FIGS. 8A-8E are views illustrating transmittance of a display panel manufactured according to one or more embodiments of the present disclosure; and

FIGS. 9A-9C are captured images of a portion of a display device according to one or more embodiments of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

The term “part” or “unit” may refer to a software component or a hardware component for performing the described function. The hardware component may include, for example, a field-programmable gate array (FPGA) or an application-specific integrated circuit (ASIC). The software component may refer to executable code and/or data used by executable code in an addressable storage medium. Thus, the software components may be, for example, object-oriented software components, class components, and/or task components, and may include processes, functions, attributes, procedures, sub-routines, segments of program code, drivers, firmware, microcode, circuitry, data, databases, data structures, tables, arrays, variables, and/or the like.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

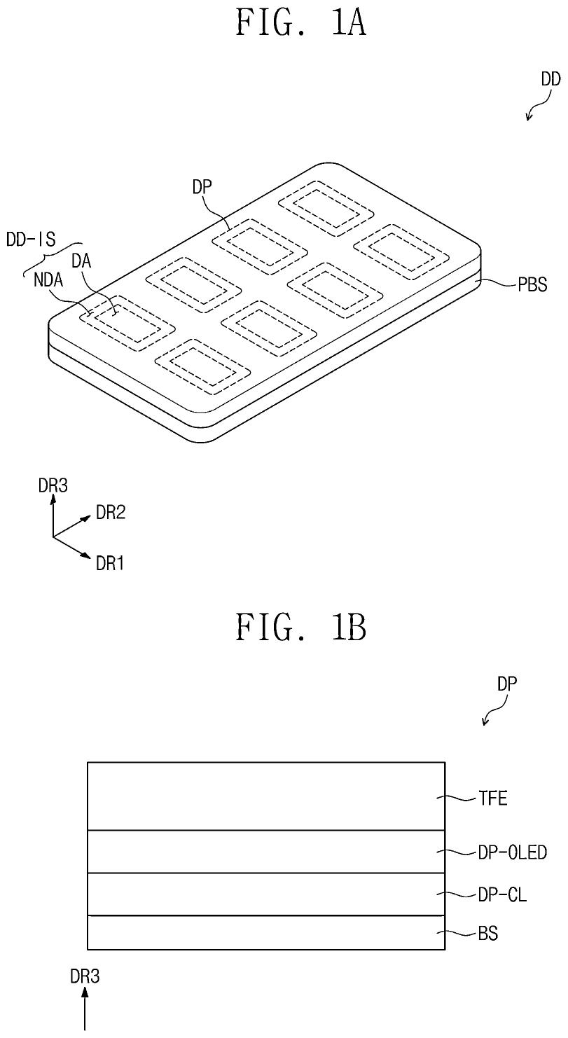

FIG. 1A is a perspective view of a display panel DP during a manufacturing process according to an embodiment of the present disclosure. FIG. 1B is a cross-sectional view of the display panel DP according to an embodiment of the present disclosure.

Referring to FIGS. 1A and 1B, the display panel DP may display an image through a display surface DD-IS. The display surface DD-IS is parallel to or substantially parallel to a plane defined by a first direction DR1 and a second direction DR2, which cross each other. An upper surface of a member disposed on an uppermost side of the display panel DP may be defined as the display surface DD-IS.

A third direction DR3 indicates a normal direction of the display surface DD-IS (e.g., a thickness direction of the display panel DP). A front surface (e.g., an upper surface) and a rear surface (e.g., a lower surface) of each layer or unit, which will be described in more detail below, are distinguished by the third direction DR3.

The display panel DP may include a display area DA and a non-display area NDA. Unit pixels are disposed at (e.g., in or on) the display area DA, and unit pixels are not disposed at (e.g., in or on) the non-display area NDA. The non-display area NDA is defined along an edge of the display surface DD-IS. The non-display area NDA may surround (e.g., around a periphery of) the display area DA. In an embodiment of the present disclosure, the non-display area NDA may be omitted or may be disposed only at (e.g., in or on) one side of the display area DA.

FIG. 1A is a perspective view illustrating one state during the process of manufacturing the display device. For example, the display panel DP may be formed on a base substrate PBS for processing. For example, a plurality of display panels DP may be disposed on a single base substrate PBS for processing. FIG. 1A illustrates an example in which eight display panels DP are formed on the single base substrate PBS for processing. However, the present disclosure is not particularly limited thereto.

The display panels DP may be separated from the base substrate PBS for processing. After the display panels DP are separated from the base substrate PBS for processing, the display panels DP may be separated from each other by a cutting process. Thereafter, an upper member such as a window, and a lower member such as a heat release layer, may be further attached to each of the display panels DP to form a display device.

The base substrate PBS for processing may be a rigid substrate on which the display panel DP is formed. For example, the base substrate PBS for processing may be a glass substrate. The base substrate PBS for processing and a base substrate BS of the display panel DP may be bonded to each other using a chemical bonding energy. In more detail, the base substrate PBS for processing and a polyimide of the base substrate BS may be bonded to each other through a covalent bond. After the display panel DP is formed, the base substrate PBS for processing may be separated from the display panel DP (e.g., may be separated from the base substrate BS of the display panel DP).

The display panel DP may include the base substrate BS, a circuit element layer DP-CL disposed on the base substrate BS, an element layer DP-OLED, and an encapsulating layer TFE. The display panel DP may generate or substantially generate an image. The display panel DP may be a light-emitting display panel. For example, the display panel DP may be an organic light-emitting display panel, an inorganic light-emitting display panel, an organic-inorganic light-emitting display panel, a quantum dot display panel, a micro light-emitting diode (LED) display panel, or a nano LED display panel.

The base substrate BS may be a member that provides a base surface on which the circuit element layer DP-CL is disposed. The base substrate BS may be a polymer substrate. For example, the base substrate BS may be a polyimide substrate. However, the present disclosure is not limited thereto, and the base substrate BS may include (e.g., may be) an inorganic layer, an organic layer, or a composite material layer.

The circuit element layer DP-CL includes a driving circuit and/or a signal line of a unit pixel PXU. The element layer DP-OLED includes a light-emitting element disposed in each of the unit pixels PXU.

The encapsulating layer TFE may protect the circuit element layer DP-CL from moisture, oxygen, and/or a foreign matter, such as dust. The encapsulating layer TFE may include at least one inorganic layer, and an organic layer. The inorganic layer may protect the circuit element layer DP-CL from moisture and/or oxygen, and the organic layer may protect the circuit element layer DP-CL from foreign matter, such as dust.

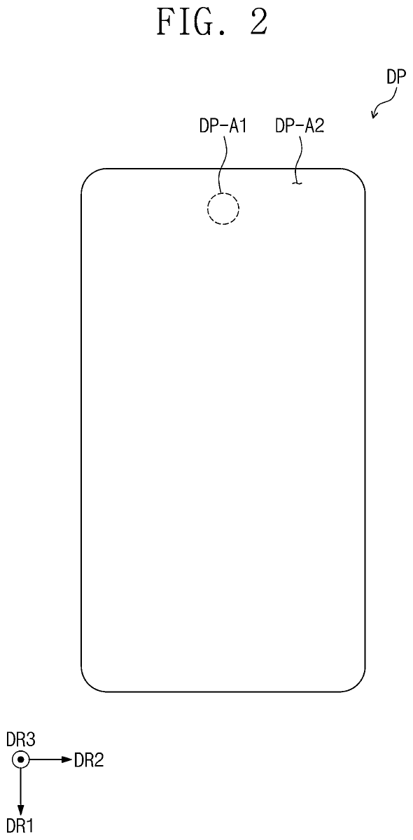

FIG. 2 is a plan view of a display panel DP according to an embodiment of the present disclosure.

Referring to FIG. 2, the display panel DP may include a first area DP-A1 and a second area DP-A2. The second area DP-A2 may be adjacent to the first area DP-A1, and may have a lower transmittance than that of the first area DP-A1.

The first area DP-A1 may be an area that overlaps with an electronic module (e.g., an electronic device or element). Thus, a transmission area may be defined in the first area DP-A1. For example, an external input (e.g., light) may be provided to the electronic module through the first area DP-A1, and/or an output from the electronic module may be emitted to the outside through the first area DP-A1. In the present embodiment, the first area DP-A1 is shown as having a circular shape. However, the present disclosure is not limited thereto, and the first area DP-A1 may have various suitable shapes, such as a polygon, an ellipse, a figure with at least one curved side, or an atypical shape.

The electronic module may include (e.g., may be) a camera module (e.g., a camera), a distance measuring sensor such as a proximity sensor, a sensor for recognizing a user's body part (e.g., a fingerprint, iris, or face), a small lamp for outputting light, and/or the like, but is not particularly limited thereto.

In order to ensure a surface area of the transmission area, the first area DP-A1 may be provided with a smaller number of pixels than that of the second area DP-A2. An area of the first area DP-A1 in which the light-emitting element is not disposed may be defined as the transmission area.

In a unit area or the same sized area, the number of first pixels disposed at (e.g., in or on) the first area DP-A1 may be smaller than the number of second pixels disposed at (e.g., in or on) the second area DP-A2. For example, the resolution of the first area DP-A1 may be about ½, ⅜, ⅓, ¼, 2/9, ⅛, 1/9, 1/16, or the like of the resolution of the second area DP-A2. For example, the resolution of the second area DP-A2 may be about 400 ppi or greater, and the resolution of the first area DP-A1 may be about 200 ppi or about 100 ppi. However, the present disclosure is not particularly limited thereto.

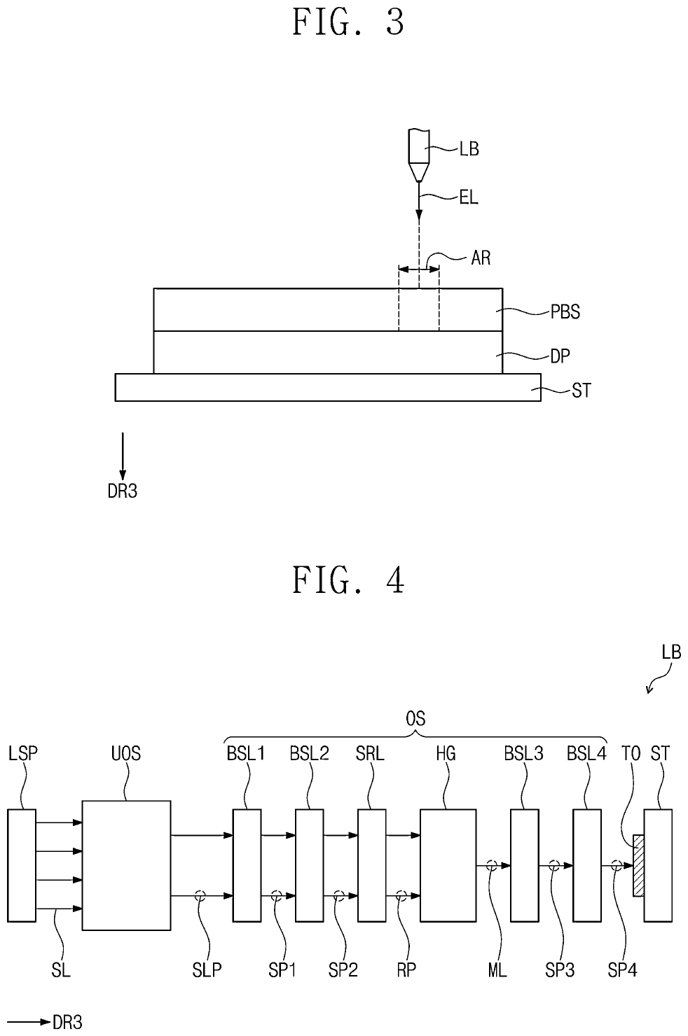

FIG. 3 is a view illustrating an operation of a laser ablation device LB according to an embodiment of the present disclosure.

Referring to FIG. 3, the laser ablation device LB may emit output light EL in a direction (e.g., the third direction DR3) from the base substrate PBS for processing toward the display panel DP. Thereafter, the display panel DP may be separated from the base substrate PBS for processing. The emitting of the output light EL may include converting a plurality of solid-state laser beams SL (e.g., see FIG. 4) into the output light EL, and emitting the output light EL in the direction from the base substrate PBS for processing toward the display panel DP.

As shown in FIG. 3, the laser ablation device LB may emit the output light EL toward the base substrate PBS for processing. The display panel DP and the base substrate PBS for processing may be disposed on a stage ST. An area irradiated with the output light EL may be defined as an irradiation area AR. The output light EL may be emitted in the direction from the base substrate PBS for processing toward the display panel DP, and a crack may occur between the base substrate PBS for processing and the display panel DP. Thereafter, the display panel DP may be separated from the base substrate PBS for processing. FIG. 3 illustrates an example in which the output light EL of the laser ablation device LB is emitted onto a portion of the base substrate PBS for processing. However, the present disclosure is not limited thereto. For example, an entirety of a flat or substantially flat surface of the base substrate PBS for processing may be irradiated with the output light EL while the laser ablation device LB or the stage ST is moved.

The laser irradiation areas AR irradiated with the laser may partially overlap with each other. The irradiation areas AR of the output light EL, which is emitted toward the base substrate PBS for processing, may overlap with each other by at least about 66.67%. For example, when a width of a beam is about 1 (e.g., 1 μm), and a first beam and a second beam overlap with each other by about 0.667 (e.g., 0.667 μm), an overlapping rate of the laser may be about 66.67%.

In a comparative example, when the intensity of the output light EL of the laser ablation device LB is high, or the overlapping rate is about 80% or higher, the output light EL may be emitted onto the display panel DP positioned below the base substrate PBS for processing. In this case, film delamination may occur in some of the layers constituting the display panel DP, and thus, a display panel DP defect may occur. For example, a pixel defect, an electrode defect, and/or the like may occur.

On the other hand, when the intensity of the output light EL is low, a crack between the base substrate PBS for processing and the display panel DP may be insufficient to separate the base substrate PBS for processing from the display panel DP. In this case, during applying of an external force to separate the base substrate PBS for processing from the display panel DP, the base substrate BS (e.g., see FIG. 1B) of the display panel DP may be detached, or another layer constituting the display panel DP may be led to film delamination.

According to an embodiment of the present disclosure, irradiation with a laser having an appropriate overlapping rate and energy density may reduce or remove the occurrence of film delamination and the occurrence of carbonization in the irradiation target, and thus, the display device defect may be reduced or removed.

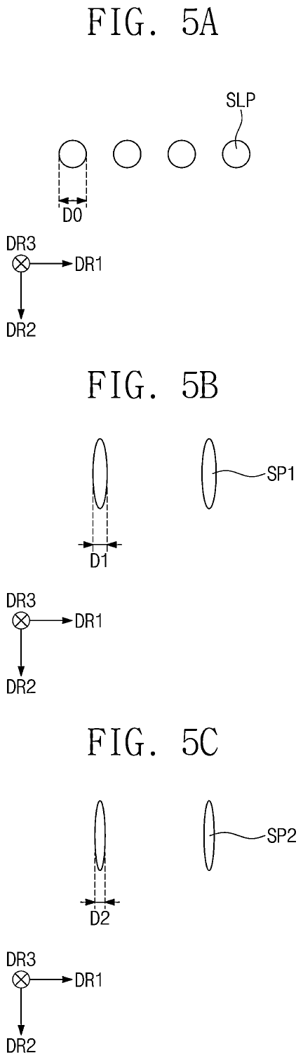

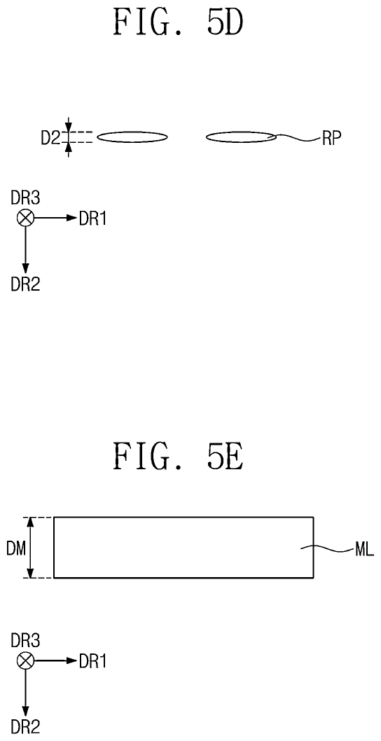

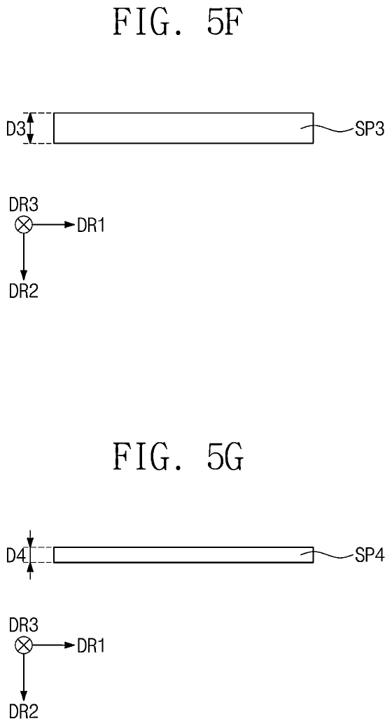

FIG. 4 is a schematic view of a laser ablation device LB according to an embodiment of the present disclosure. FIGS. 5A through 5G are views illustrating a shape of a laser beam according to one or more embodiments of the present disclosure.

Referring to FIGS. 4 and 5A to 5G, the laser ablation device LB may include a laser irradiation part LSP, an optical system OS, and a stage ST. The laser irradiation part LSP may emit a plurality of solid-state laser beams SL. The plurality of solid-state laser beams SL may be ultraviolet light having a wavelength of about 343 nm, and may have a nanosecond (ns) pulse width. The plurality of solid-state laser beams SL may include (e.g., may be) four solid-state laser beams SL. While FIG. 4 illustrates four solid-state laser beams SL as an example, the number of the plurality of solid-state laser beams SL is not limited thereto. For example, the number of the plurality of solid-state laser beams SL may be four or greater.

The optical system OS may convert the plurality of solid-state laser beams SL into the output light EL (e.g., see FIG. 3). The output light EL may have a linear shape. An irradiation target TO irradiated with the output light EL may be disposed on the stage ST. The irradiation target TO may be the base substrate PBS for processing and the display panel DP.

The optical system OS may include a first molded lens BSL1, a second molded lens BSL2, a shape rotation lens SRL, a homogenizer HG, a third molded lens BSL3, and a fourth molded lens BSL4. The plurality of solid-state laser beams SL, which are emitted by the laser irradiation part LSP, may be converted into the output light EL by passing through the first molded lens BSL1, the second molded lens BSL2, the shape rotation lens SRL, the homogenizer HG, the third molded lens BSL3, and the fourth molded lens BSL4 in sequence.

The converting of the plurality of solid-state laser beams SL into the output light EL may include changing the shapes of the plurality of solid-state laser beams SL to first shapes SP1, changing the first shapes SP1 of the plurality of solid-state laser beams to a plurality of solid-state laser beams having second shapes SP2 different from the first shapes SP1, rotating the shapes of the plurality of solid-state laser beams, mixing the plurality of solid-state laser beams to output mixed light ML, changing a shape of the mixed light ML to a third shape SP3, and changing the third shape SP3 of a plurality of solid-state laser beams to a plurality of solid-state laser beams having a fourth shape SP4 different from the third shape SP3.

The first molded lens BSL1 may be disposed between the laser irradiation part LSP and the second molded lens BSL2. The first molded lens BSL1 may be a cylindrical lens. The first molded lens BSL1 may change initial shapes SLP of the plurality of solid-state laser beams SL to the first shapes SP1.

The second molded lens BSL2 may be disposed between the first molded lens BSL1 and the shape rotation lens SRL. The second molded lens BSL2 may be a cylindrical lens. The second molded lens BSL2 may change shapes of the plurality of solid-state laser beams SL from the first shapes SP1 to the second shapes SP2. The second shapes SP2 may be different from the first shapes SP1.

The initial shapes SLP of the plurality of solid-state laser beams SL may be circular. Each of the first shapes SP1 and the second shapes SP2 may be an ellipse. A diameter D0 (e.g., see FIG. 5A) of the initial shapes SLP may be greater than a minor axis D1 (e.g., see FIG. 5B) of the first shapes SP1, and the minor axis D1 of the first shapes SP1 may be greater than a minor axis D2 (e.g., see FIG. 5C) of the second shapes SP2. A minor axis refers to a shortest diameter of an ellipse.

The shape rotation lens SRL may be disposed between the second molded lens BSL2 and the homogenizer HG. The shape rotation lens SRL may rotate the second shapes SP2 of the plurality of solid-state laser beams SL passing through the second molded lens BSL2. For example, the shape rotation lens SRL may rotate, by about 90 degrees, the second shapes SP2 of the plurality of solid-state laser beams SL passing through the second molded lens BSL2, and thus, may convert the second shapes SP2 to rotated patterns RP (e.g., see FIG. 5D).

The homogenizer HG may be disposed between the shape rotation lens SRL and the third molded lens BSL3. The homogenizer HG may mix the plurality of solid-state laser beams SL passing through the shape rotation lens SRL to output the mixed light ML (e.g., see FIG. 5E).

The third molded lens BSL3 may be disposed between the homogenizer HG and the fourth molded lens BSL4. The third molded lens BSL3 may be a cylindrical lens. The third molded lens BSL3 may change the shape of the mixed light ML to the third shape SP3 (e.g., see FIG. 5F).

The fourth molded lens BSL4 may be disposed between the third molded lens BSL3 and the stage ST. The fourth molded lens BSL4 may be a cylindrical lens. The fourth molded lens BSL4 may change the third shape SP3 of the mixed light ML passing through the third molded lens BSL3 to the fourth shape SP4 (e.g., see FIG. 5G). The fourth shape SP4 may be different from the third shape SP3. A radius of curvature of the fourth molded lens BSL4 may be about 5200 mm to about 7000 mm. The radius of curvature of the fourth molded lens BSL4 may be limited as above, so that a minor axis of the output light EL may be adjusted to have a semi-super Gaussian profile. In addition, the fourth molded lens BSL4 is disposed between the third molded lens BSL3 and the stage ST, so that aberration may be minimized or reduced.

The mixed light ML may have a shape in which the plurality of solid-state laser beams SL are combined with one another. In the present embodiment, each of the mixed light ML, the third shape SP3, and the fourth shape SP4 is illustrated as having a rectangular shape, but the present disclosure is not limited thereto, and they may have various suitable shapes, such as a circular shape, an elliptical shape, or an atypical shape. A width D3 of the third shape SP3 may be smaller than a width DM of the mixed light ML. A width D4 of the fourth shape SP4 may be smaller than the width D3 of the third shape SP3.

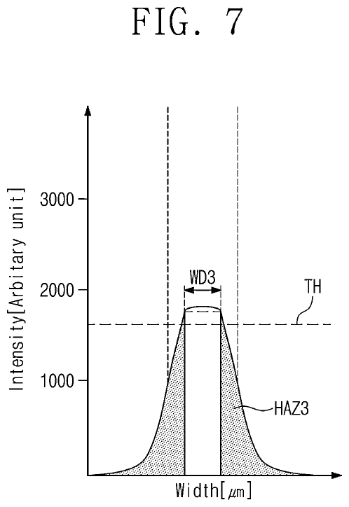

The minor axis of the output light EL, which is converted in the optical system OS, may have the semi-super Gaussian profile. For example, when viewed in a moving direction of the output light EL, the energy intensity measured in a minor-axis direction may have the semi-super Gaussian profile. The semi-super Gaussian may be of order 2 to order 2.4. The semi-super Gaussian profile of the minor axis of the output light EL will be described in more detail below with reference to FIG. 7.

The laser ablation device LB may further include a lower optical system UOS. The lower optical system UOS may be disposed between the laser irradiation part LSP and the optical system OS. The lower optical system UOS may combine the plurality of solid-state laser beams SL with one another, which are provided by the laser irradiation part LSP, to provide the optical system OS with a plurality of solid-state laser beams SL having the initial shapes SLP, of which a number thereof is smaller than the number of the plurality of solid-state laser beams SL. For example, the laser irradiation part LSP may emit four solid-state laser beams SL, and the lower optical system UOS may combine the four solid-state laser beams SL with one another to provide the optical system OS with two solid-state laser beams SL having the initial shapes SLP.

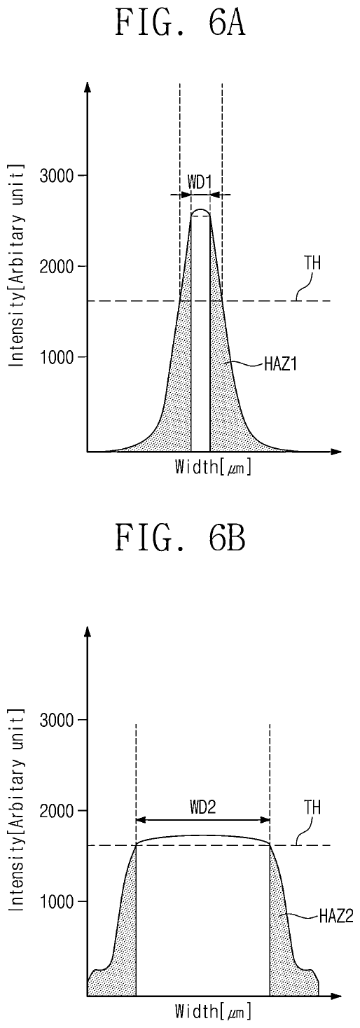

FIGS. 6A and 6B are Gaussian graphs of a laser ablation device according to a comparative example. FIG. 7 is a Gaussian graph of the laser ablation device LB according to an embodiment of the present disclosure.

Referring to FIGS. 6A, 6B, and 7, an X-axis coordinate in each of the graphs represents a minor-axis beam width on the irradiation target TO (e.g., see FIGS. 3 and 4) irradiated with a laser, and a Y-axis coordinate in each of the graphs represents an energy intensity per unit area of the output light.

The graph of FIG. 6A shows the intensity of the output light of a typical solid-state laser beam. The graph of FIG. 6A has a sharp Gaussian shape, and may be a Gaussian graph of order 1.7 to order 1.9. The graph of FIG. 6B shows the intensity of output light of a typical gas laser beam. The graph of FIG. 6B has a super Gaussian shape that is a flat-top shape in which an upper surface of a minor axis is gentle, and may be a Gaussian graph of order 10 or higher. FIG. 7 shows the intensity of the output light according to an embodiment of the present disclosure. The graph of FIG. 7 has a semi-super Gaussian shape, and may be a Gaussian graph of order 2 to order 2.4. As the order of a Gaussian graph is higher, an upper surface of the Gaussian graph may be gentler.

In each of the graphs of FIGS. 6A to 7, there is an energy zone HAZ1, HAZ2, or HAZ3. The energy zone HAZ1, HAZ2, or HAZ3 may be a zone in which carbonization occurs. An energy (e.g., a predetermined energy) for breaking bonds is desired to separate the display panel DP and the base substrate PBS for processing (e.g., see FIG. 3) from each other. The energy (e.g., the predetermined energy) may be defined as a threshold TH. For example, when the energy intensity of laser does not exceed the threshold TH, the display panel DP and the base substrate PBS for processing may not be separated from each other. A portion, which contributes to the separation of the display panel DP and the base substrate PBS for processing from each other, corresponds to a portion at which the value is about 90 percent or above of the maximum of the Gaussian profile.

The Gaussian graph of FIG. 6A has a sharp shape. Thus, the portion at which the value is about 90 percent or above of the maximum of the Gaussian profile is formed above the threshold TH, and the range of a first energy zone HAZ1 above the threshold TH is wide. In this case, the display panel DP and the base substrate PBS for processing may be separated from each other. However, carbonization may occur, and as more carbonization occurs, the transmittance of the display panel DP may become lower. A width WD1 at which the value is about 90 percent of the maximum of the Gaussian profile in FIG. 6A may be about 13 micrometers or less.

The super Gaussian graph of FIG. 6B has a flat-top shape in which an upper surface is gentle. Thus, a portion at which the value is about 90 percent or above of the maximum of the Gaussian profile is formed around the threshold TH, and the range of a second energy zone HAZ2 above the threshold TH may not exist or may be narrow. In this case, the display panel DP and the base substrate PBS for processing may be separated from each other, and less carbonization may occur, thereby making it possible to manufacture the display panel DP (e.g., see FIG. 1A) with the high transmittance. However, when the portion at which the value is about 90 percent or above of the maximum of the Gaussian profile does not exceed the threshold TH, the energy used to separate the display panel DP and the base substrate PBS for processing from each other may be insufficient due to low energy density. In addition, the Gaussian profile of FIG. 6B corresponds to a shape which may not be achieved in the solid-state laser beam, and a gas laser ablation device may need more production facility costs and time than those of a solid-state laser ablation device. A width WD2 at which the value is about 90 percent of the maximum of the Gaussian profile in FIG. 6B may be about 400 micrometers.

Thus, when a laser beam with the minor axis having the semi-super Gaussian profile shape as illustrated in FIG. 7, which is an intermediate shape between the shapes of the graphs of FIGS. 6A and 6B, is used, occurrence of carbonization in the irradiation target TO may be reduced or removed, and the production facility costs and time may be saved. A width WD3 at which the value is about 90 percent of the maximum of the Gaussian profile in FIG. 7 may be about 18 micrometers to about 40 micrometers. The energy density per unit area of the output light EL (e.g., see FIG. 3), which is delivered to each irradiation target TO, may be about 130 mJ/cm² to about 200 mJ/cm².

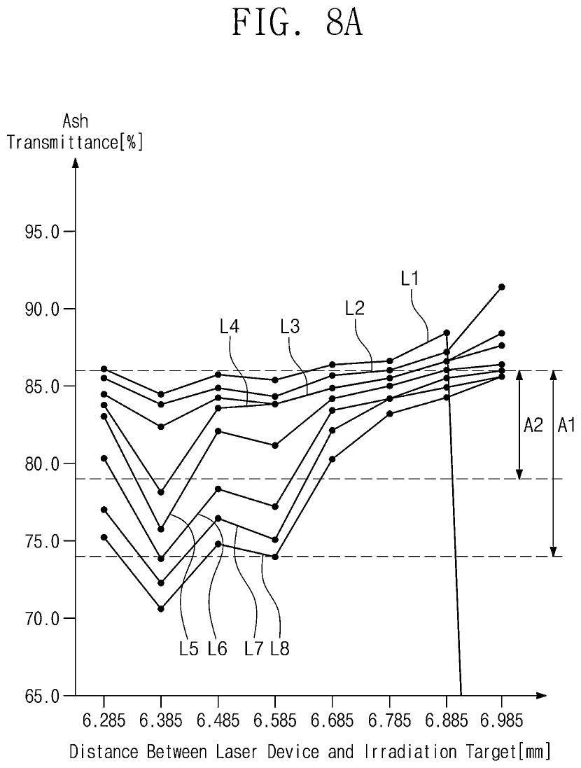

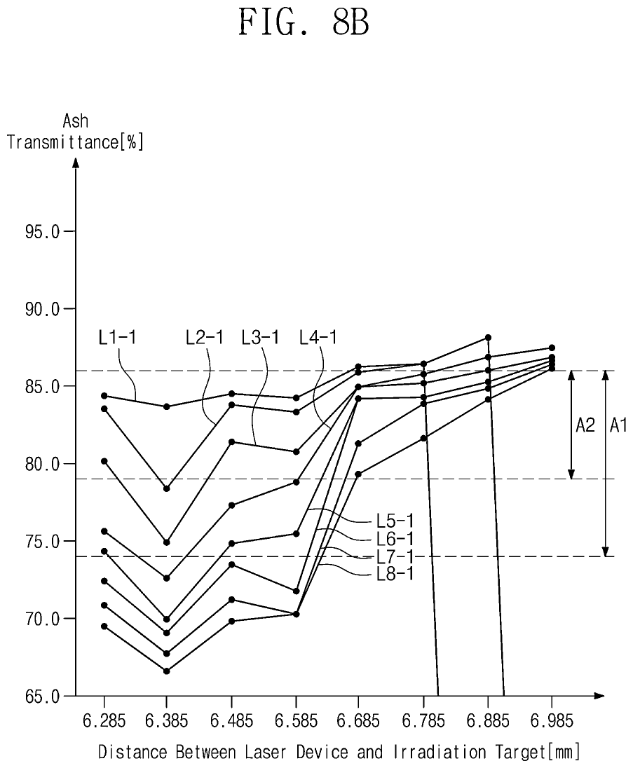

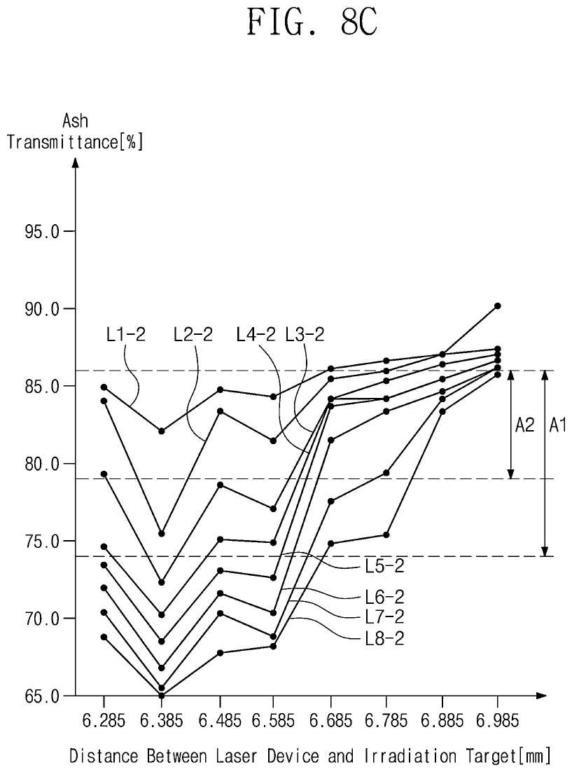

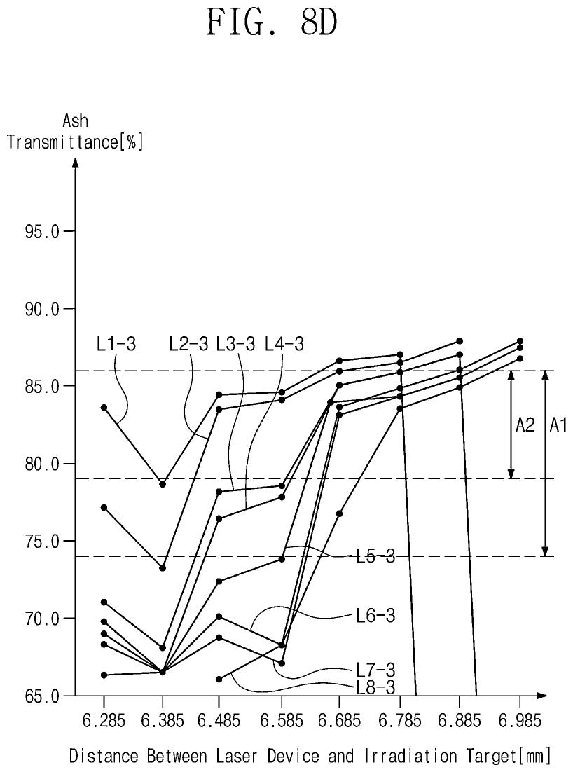

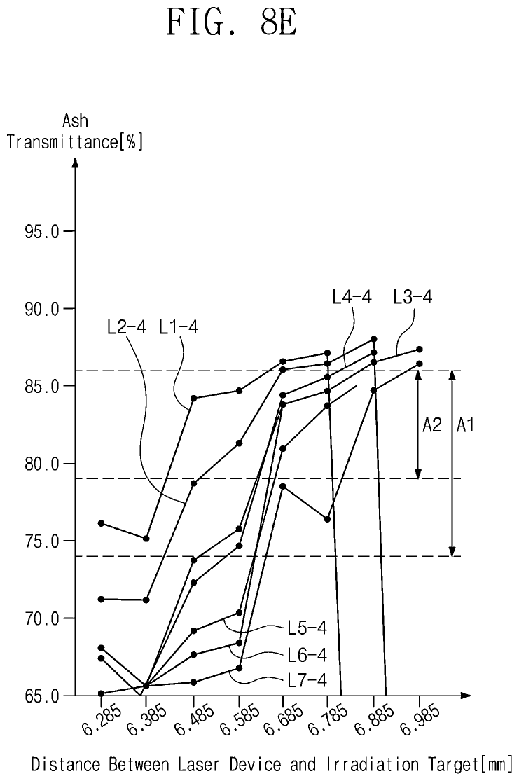

FIGS. 8A through 8E are views illustrating transmittance of the display panel DP manufactured according to one or more embodiments of the present disclosure.

Referring to FIGS. 3 and 8A to 8E, the laser ablation device LB may emit the output light EL toward the irradiation target TO (e.g., see FIG. 4) while being moved. The laser irradiation areas AR irradiated with the laser may partially overlap with each other. For example, when the width of a beam is about 1 (e.g., 1 μm), and when a first beam and a second beam overlap with each other by about 0.667 (e.g., 0.667 μm), an overlapping rate of the laser may be about 66.67%. In more detail, the overlapping rate may be defined as: overlapping rate (%)=(1-1/(times of laser irradiation onto a certain area))*100. When the overlapping rate of the laser ablation device LB is high, carbonization or film delamination may be caused. When the overlapping rate is low, detachment between the display panel DP and the base substrate PBS for processing may not occur.

FIG. 8A is a view illustrating the transmittance varying depending on a distance between the laser ablation device LB and the irradiation target TO (e.g., see FIG. 4) when the overlapping rate is about 66.67%. First to eight graphs L1, L2, L3, L4, L5, L6, L7 and L8 each show the transmittance varying depending on the distance between the laser ablation device LB and the irradiation target TO when irradiated with the laser of which output is adjusted over eight levels. For example, the first graph L1 may show the transmittance varying depending on the distance between the laser ablation device LB and the irradiation target TO when irradiated with the laser having a first intensity. The second to eight graphs L2, L3, L4, L5, L6, L7 and L8 each show the transmittance varying depending on the distance between the laser ablation device LB and the irradiation target TO when irradiated with laser having gradually higher intensities than the first intensity.

FIG. 8B is a view illustrating the transmittance varying depending on the distance between the laser ablation device LB and the irradiation target TO (e.g., see FIG. 4) when the overlapping rate is about 71.43%. First to eight graphs L1-1, L2-1, L3-1, L4-1, L5-1, L6-1, L7-1 and L8-1 each show the transmittance varying depending on the distance between the laser ablation device LB and the irradiation target TO when irradiated with the laser of which output is adjusted over eight levels. The output of the laser corresponding to the first graph L1-1 may be the lowest, and the output of the laser corresponding to the eighth graph L8-1 may be the highest.

FIG. 8C is a view illustrating the transmittance varying depending on the distance between the laser ablation device LB and the irradiation target TO (e.g., see FIG. 4) when the overlapping rate is about 75%. First to eight graphs L1-2, L2-2, L3-2, L4-2, L5-2, L6-2, L7-2 and L8-2 each show the transmittance varying depending on the distance between the laser ablation device LB and the irradiation target TO (e.g., see FIG. 4) when irradiated with the laser of which output is adjusted over eight levels. The output of the laser corresponding to the first graph L1-2 may be the lowest, and the output of the laser corresponding to the eighth graph L8-2 may be the highest.

FIG. 8D is a view illustrating the transmittance varying depending on the distance between the laser ablation device LB and the irradiation target TO (e.g., see FIG. 4) when the overlapping rate is about 80%. First to eight graphs L1-3, L2-3, L3-3, L4-3, L5-3, L6-3, L7-3 and L8-3 each show the transmittance varying depending on the distance between the laser ablation device LB and the irradiation target TO (e.g., see FIG. 4) when irradiated with the laser of which output is adjusted over eight levels. The output of the laser corresponding to the first graph L1-3 may be the lowest, and the output of laser corresponding to the eighth graph L8-3 may be the highest.

FIG. 8E is a view illustrating the transmittance varying depending on the distance between the laser ablation device LB and the irradiation target TO (e.g., see FIG. 4) when the overlapping rate is about 83.34%. First to eight graphs L1-4, L2-4, L3-4, L4-4, L5-4, L6-4, L7-4 and L8-4 each show the transmittance varying depending on the distance between the laser ablation device LB and the irradiation target TO (e.g., see FIG. 4) when irradiated with the laser of which output is adjusted over eight levels. The output of the laser corresponding to the first graph L1-4 may be the lowest, and the output of the laser corresponding to the eighth graph L8-4 may be the highest.

An X axis in each of the graphs corresponds to the distance between the laser ablation device LB and the irradiation target TO (e.g., see FIG. 4), and a Y axis in each of the graphs corresponds to a transmittance value of the display panel DP from which the base substrate PBS for processing is removed (e.g., see FIG. 3). The minor axis of the laser beam in each of the graphs has the semi-super Gaussian profile illustrated in FIG. 7.

As shown in the graphs, as the energy intensity of the laser beam is higher, the transmittance of the display panel DP becomes lower, and as the energy intensity of the laser beam is lower, the transmittance of the display panel DP becomes higher. When the energy intensity is high, a pixel defect or an electrode breakage defect may occur. When the energy intensity is low, the display panel DP may not be separated from the base substrate PBS for processing, and thus, may be forcibly separated to cause a defect in which the base substrate BS or another layer constituting the display panel DP (e.g., see FIG. 1B) is separated.

A first safe area A1 may be defined as an area having a transmittance of about 74% to about 86%. The first safe area A1 may be an area in which the electrode defect, and the defect in which another layer is separated, do not occur. In other words, when irradiation is performed by adjusting the energy of the laser beam so that the transmittance of the display panel DP is about 74% to about 86%, the electrode defect and the defect in which another layer is separated may be prevented or substantially prevented in the display panel DP.

A second safe area A2 may be defined as an area having a transmittance of about 79% to about 86%. The second safe area A2 may be an area in which the pixel defect does not occur. In other words, when irradiation is performed by adjusting the energy of the laser beam so that the transmittance of the display panel DP is about 79% to about 86%, the electrode defect, the defect in which another layer is separated, and the pixel defect may be prevented or substantially prevented.

As illustrated in FIGS. 8A through 8E, it may be understood that as the overlapping rate is higher, there are more laser graphs deviating from the first safe area A1 or the second safe area A2. As illustrated in FIG. 8A, when the overlapping rate is about 66.67%, the defect of the display panel DP may be reduced or removed, and a process margin area may be larger. Thus, when the display panel DP is separated from the base substrate PBS for processing by irradiation with the laser having the overlapping rate range according to an embodiment of the present disclosure, the display panel DP according to an embodiment of the present disclosure may have a transmittance of about 79% to about 86%.

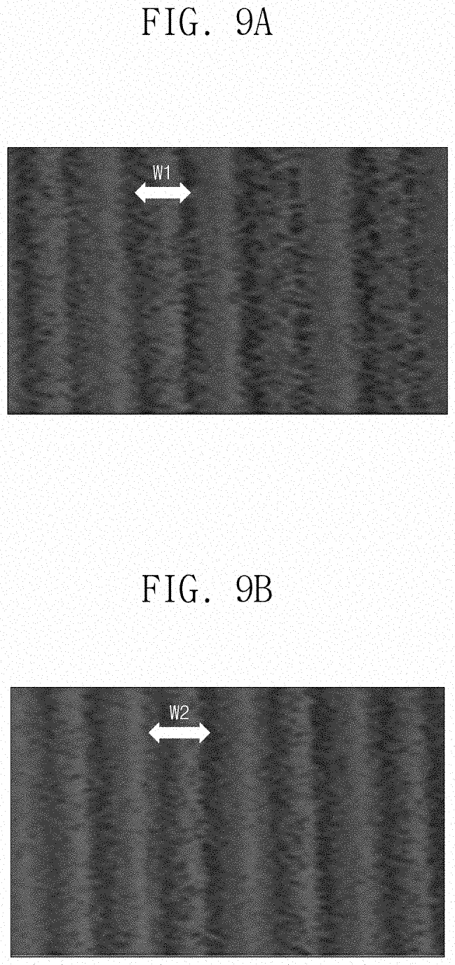

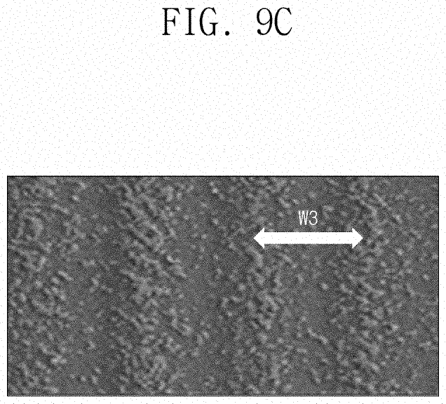

FIGS. 9A through 9C are captured images of a portion of a display panel DP according to one or more embodiments of the present disclosure.

FIGS. 9A through 9C are captured images of the display device after the base substrate PBS for processing is separated from the display panel DP. A width W1, W2, or W3 of an irradiation trace of the output light EL appears on the display panel DP, and is analyzed through microscope imaging so that the shape of the output light EL may be identified. The width W1, W2, or W3 of the irradiation trace of the output light EL corresponds to a width at the maximum of the Gaussian profile. Thus, based on the width W1, W2, or W3 of the irradiation trace of the output light, which is obtained by analyzing the display panel DP, the width at the maximum of the Gaussian profile may be identified, and the order of the Gaussian profile may be identified. According to an embodiment of the present disclosure, the width W1, W2, or W3 of the irradiation trace of the output light, which appears on the display panel DP, may be about 18 micrometers to about 40 micrometers.

According to one or more embodiments of the present disclosure described above, when the solid-state laser beam, of which a minor axis thereof has the semi-super Gaussian profile, is emitted, occurrence of film delamination and occurrence of carbonization in the irradiation target may be reduced or removed, and the production facility costs and time may be saved. In addition, the solid-state laser beam, which has the overlapping rate of at least about 66.67% and has the semi-super Gaussian profile, is emitted, so that the display device defect may be reduced or removed, and the process margin area may become larger.

Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A laser ablation device comprising:
a laser irradiation part configured to emit a plurality of solid-state laser beams;
an optical system configured to convert the plurality of solid-state laser beams into output light; and
a stage on which an irradiation target irradiated with the output light are disposed,
wherein a minor axis of the output light has a semi-super Gaussian profile of order 2 to order 2.4.

2. The laser ablation device of claim 1, wherein an energy intensity per unit area of the output light delivered to the irradiation target is about 130 mJ/cm² to about 200 mJ/cm².

3. The laser ablation device of claim 1, wherein the optical system comprises:
a first molded lens configured to change initial shapes of the plurality of solid-state laser beams into first shapes; and
a second molded lens configured to change the first shapes of the plurality of solid-state laser beams into second shapes different from the first shapes.

4. The laser ablation device of claim 3, wherein the optical system further comprises a shape rotation lens configured to rotate the second shapes of the plurality of solid-state laser beams passed through the second molded lens.

5. The laser ablation device of claim 4, wherein the shape rotation lens rotates, by about 90 degrees, the second shapes of the plurality of solid-state laser beams passed through the second molded lens.

6. The laser ablation device of claim 4, wherein the optical system further comprises a homogenizer configured to mix the plurality of solid-state laser beams passed through the shape rotation lens to output mixed light.

7. The laser ablation device of claim 6, wherein the optical system further comprises:
a third molded lens configured to change a shape of the mixed light to a third shape; and
a fourth molded lens configured to change the third shape of the mixed light passed through the third molded lens into a fourth shape different from the third shape.

8. The laser ablation device of claim 7, wherein each of the first molded lens, the second molded lens, the third molded lens, and the fourth molded lens is a cylindrical lens.

9. The laser ablation device of claim 7, wherein a radius of curvature of the fourth molded lens is about 5200 mm to about 7000 mm.

10. The laser ablation device of claim 3, wherein each of the first shapes and the second shapes is an ellipse.

11. The laser ablation device of claim 1, wherein initial shapes of the plurality of solid-state laser beams are circular, and a number of the plurality of solid-state laser beams is at least 4.

12. The laser ablation device of claim 1, further comprising a lower optical system configured to combine the plurality of solid-state laser beams emitted by the laser irradiation part with one another, and provide the optical system with a plurality of solid-state laser beams having a number that is smaller than the number of the plurality of solid-state laser beams emitted by the laser irradiation part.

13. The laser ablation device of claim 1, wherein irradiation regions of the output light emitted toward the irradiation target overlap with each other by at least about 66.7%.

14. A laser ablation device comprising:
a laser irradiation part configured to emit a plurality of solid-state laser beams;
an optical system configured to convert the plurality of solid-state laser beams into output light; and
a stage on which an irradiation target irradiated with the output light are disposed,
wherein a minor axis of the output light has a semi-super Gaussian profile, and a width at about 90% of a maximum of the semi-super Gaussian profile is about 18 micrometers to about 40 micrometers.

15. The laser ablation device of claim 14, wherein the semi-super Gaussian profile is of order 2 to order 2.4.

16. A display device manufacturing method comprising:
forming a display panel on a base substrate for processing; and
emitting output light to separate the display panel from the base substrate for processing,
wherein the emitting of the output light comprises:
converting a plurality of solid-state laser beams into the output light, and
emitting the output light in a direction from the base substrate for processing toward the display panel,
wherein a minor axis of the output light has a semi-super Gaussian profile of order 2 to order 2.4.

17. The display device manufacturing method of claim 16, wherein the converting of the plurality of solid-state laser beams into the output light comprises:
changing shapes of the plurality of solid-state laser beams to first shapes;
changing the first shapes of the plurality of solid-state laser beams into second shapes different from the first shapes;
rotating the second shapes of the plurality of solid-state laser beams; and
mixing the plurality of solid-state laser beams with one another to output mixed light.

18. The display device manufacturing method of claim 17, wherein the converting of the plurality of solid-state laser beams into the output light further comprises:
changing a shape of the mixed light to a third shape; and
changing the third shape of the plurality of solid-state laser beams into a fourth shape different from the third shape.

19. The display device manufacturing method of claim 16, wherein the display panel comprises a first area, and a second area adjacent to the first area, the second area having a lower transmittance than that of the first area.

20. The display device manufacturing method of claim 16, wherein the display panel has a transmittance of about 79% to about 86%.
